(19) United States
(12) Patent Application Publication
(10) Pub. No.: US 2025/0142750 A1
(43) Pub. Date: May 1, 2025

(54) DISPLAY DEVICE

(71) Applicant: LG ELECTRONICS INC., Seoul (KR)

(72) Inventors: Kyeungsoo JEONG, Seoul (KR); Jinhaeng JANG, Seoul (KR)

(73) Assignee: LG ELECTRONICS INC., Seoul (KR)

(21) Appl. No.: 18/692,728

(22) PCT Filed: Sep. 16, 2021
(86) PCT No.: PCT/KR2021/012667

§ 371 Date: Mar. 15, 2024

(51) Int. Cl. H05K 5/02; H01F 27/24; H01F 27/28; H01F 27/30

(52) U.S. Cl. CPC H05K 5/0247; H01F 27/24; H01F 27/2823; H01F 27/306

(57) ABSTRACT

Disclosed is a display device. The display device may include: a display panel; a frame which is located in a rear of the display panel, and to which the display panel is coupled; a back cover covering a rear of the frame; a power supply board which is located between the frame and the back cover, and which is coupled to the frame; and a line filter which is located between the power supply board and the back cover, and which is coupled to the power supply board, wherein the line filter may include: an inductor; and a core which shields at least two side surfaces of the inductor.

### TECHNICAL FIELD

The present disclosure relates to a display device. More particularly, the present disclosure relates to a display device having a line filter.

### BACKGROUND ART

As information society develops, the demand for display devices is also increasing in various forms. In response to this, various display devices such as Liquid Crystal Display Device (LCD), Electro luminescent Display (ELD), Vacuum Fluorescent Display (VFD), Organic Light Emitting Diode (OLED), and Micro LED have been researched and used in recent years.

Among these, a liquid crystal panel includes a TFT substrate and a color filter substrate that face each other with a liquid crystal layer interposed therebetween, and may display an image by using light provided from a backlight unit. In addition, an OLED panel may display an image by depositing an organic material layer capable of self-emitting light on a substrate on which a transparent electrode is formed. In particular, a display device equipped with OLED panel has an advantage of being implemented in an ultra-thin type as it does not require a backlight unit.

Recently, much research has been conducted on a structure that may effectively reduce vibration or noise (particularly, low-frequency noise) of metal parts generated when displaying high-definition images on a large-screen ultra-thin display device.

### DETAILED DESCRIPTION OF INVENTION

### Technical Problems

An object of the present disclosure is to solve the above-described problems and other problems.

Another object may be to provide a display device that may shield magnetic flux leaking from a line filter.

Another object may be to provide a core made of a material that may effectively shield magnetic flux leaking from a line filter.

Another object may be to provide a structure that may effectively shield magnetic flux leaking from an inductor depending on the type of inductor of a line filter.

Another object may be to provide a structure that may minimize an increase in the thickness of a display device due to the shielding structure of a line filter.

Another object may be to provide various examples of core materials.

### Technical Solution

In accordance with an aspect of the present disclosure to achieve the above and other objectives, a display device may include: a display panel; a frame which is located in a rear of the display panel, and to which the display panel is coupled; a back cover covering a rear of the frame; a power supply board which is located between the frame and the back cover, and which is coupled to the frame; and a line filter which is located between the power supply board and the back cover, and which is coupled to the power supply board, wherein the line filter may include: an inductor; and a core which shields at least two side surfaces of the inductor.

### Effect of Invention

The effects of the display device according to the present disclosure will be described as follows.

According to at least one of the embodiments of the present disclosure, it is possible to provide a display device that may shield magnetic flux leaking from a line filter.

According to at least one of the embodiments of the present disclosure, it is possible to provide a core made of a material that may effectively shield magnetic flux leaking from a line filter.

According to at least one of the embodiments of the present disclosure, it is possible to provide a structure that may effectively shield magnetic flux leaking from an inductor depending on the type of inductor of a line filter.

According to at least one of the embodiments of the present disclosure, it is possible to provide a structure that may minimize an increase in the thickness of a display device due to the shielding structure of a line filter.

According to at least one of the embodiments of the present disclosure, it is possible to provide various examples of core materials.

Further scope of applicability of the present disclosure will become apparent from the following detailed description. However, it should be understood that the detailed description and specific embodiments such as preferred embodiments of the present disclosure are given by way of illustration only, since various changes and modifications within the spirit and scope of the present disclosure may be clearly understood by those skilled in the art.

### BRIEF DESCRIPTION OF THE DRAWING

FIGS. 1 to 24 are diagrams illustrating examples of a display device according to embodiments of the present disclosure.

### MODE FOR CARRYING OUT THE INVENTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected with” another element, there may be intervening elements present. In contrast, it will be understood that when an element is referred to as being “directly connected with” another element, there are no intervening elements present.

A singular representation may include a plural representation unless context clearly indicates otherwise.

In the present application, it should be understood that the terms “comprises, includes,” “has,” etc. specify the presence of features, numbers, steps, operations, elements, components, or combinations thereof described in the specification, but do not preclude the presence or addition of one or more other features, numbers, steps, operations, elements, components, or combinations thereof.

Direction indications of up (U), down (D), left (Le), right (Ri), front (F), and rear (R) shown in the drawings are only for convenience of explanation, and the technical concept disclosed in this specification is not limited thereto.

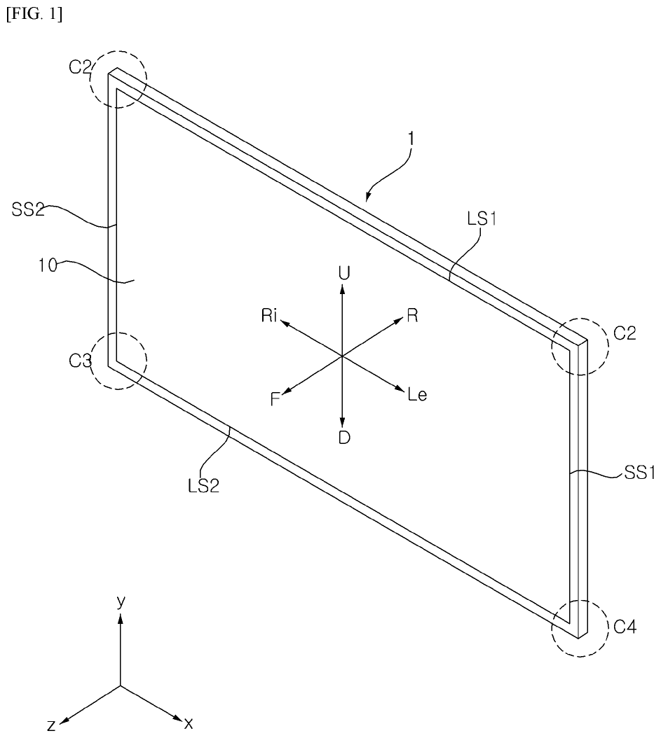

Referring to FIG. 1, a display device 1 may include a display panel 10. The display panel 10 may display a screen.

The display device 1 may include a first long side LS1, a second long side LS2 opposite to the first long side LS1, a first short side SS1 adjacent to the first and second long sides LS1 and LS2, and a second short side SS2 opposite to the first short side SS1. Meanwhile, for convenience of description, it is illustrated that the length of the long side LS1, LS2 is larger than the length of the short side SS1, SS2, but it may also be possible that the lengths of the long side LS1, LS2 is substantially equal to the length of short side SS1, SS2.

The direction parallel to the long sides LS1 and LS2 of the display device 1 may be referred to as a left-right direction. The direction parallel to the short sides SS1 and SS2 of the display device 1 may be referred to as a vertical direction. The direction perpendicular to the long sides LS1 and LS2 and the short sides SS1 and SS2 of the display device 1 may be referred to as a front-rear direction.

The direction in which the display panel 10 displays images may be referred to as a forward direction (F, z), and the opposite direction may be referred to as a rearward direction R. A side of the first long side LS1 may be referred to as an upper side (U, y). A side of the second long side LS2 may be referred to as a lower side D. A side of the first short side SS1 may be referred to as a left side (Le, x). A side of the second short side SS2 may be referred to as a right side Ri.

The first long side LS1, the second long side LS2, the first short side SS1, and the second short side SS2 may be referred to as an edge of the display device 1. In addition, a point where the first long side LS1, the second long side LS2, the first short side SS1, and the second short side SS2 meet each other may be referred to as a corner.

For example, a point where the first short side SS1 and the first long side LS1 meet may be referred to as a first corner C1. A point where the first long side LS1 and the second short side SS2 meet may be referred to as a second corner C2. A point where the second short side SS2 and the second long side LS2 meet may be referred to as a third corner C3. A point where the second long side LS2 and the first short side SS1 meet may be referred to as a fourth corner C4.

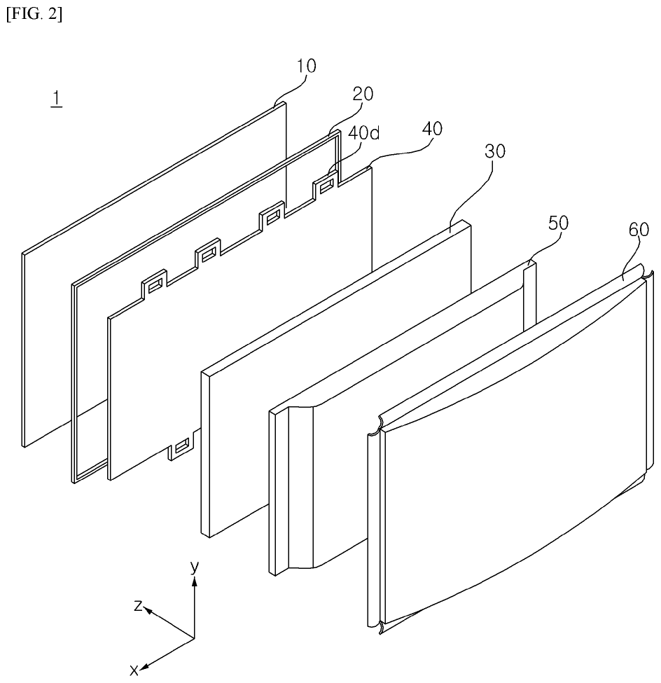

Referring to FIG. 2, a display device 1 may include a display panel 10, a guide panel 20, a backlight unit 30, 40, a frame 50, and a back cover 60.

The display panel 10 may form the front surface of the display device 1, and may display an image. The display panel 10 may display an image by having a plurality of pixels that output Red, Green or Blue (RGB) for each pixel in accordance with a timing. The display panel 10 may be divided into an active area where an image is displayed and a de-active area where an image is not displayed. The display panel 10 may include a front substrate and a rear substrate that are opposite to each other with a liquid crystal layer interposed therebetween. The display panel 10 may be referred to as an LCD panel.

The front substrate may include a plurality of pixels consisting of red, green, and blue subpixels. The front substrate may output a light corresponding to the color of red, green, or blue depending on a control signal.

The rear substrate may include switching elements. The rear substrate may switch a pixel electrode. For example, the pixel electrode may change the molecular arrangement of a liquid crystal layer according to an externally input control signal. The liquid crystal layer may include liquid crystal molecules. The arrangement of liquid crystal molecules may change in response to a voltage difference generated between the pixel electrode and a common electrode. The liquid crystal layer may transmit or block a light provided from the backlight unit 30, 40 to the front substrate.

The guide panel 20 may surround the circumference of the display panel 10, and cover the side surface of the display panel 10. The guide panel 20 may be coupled to the display panel 10 or may support the display panel 10. The guide panel 20 may be referred to as a side frame or a middle cabinet.

The backlight unit 30, 40 may be located in a rear of the display panel 10. The backlight unit 30, 40 may include light sources. The backlight unit 30, 40 may be coupled to the frame 50 in front of the frame 50. The backlight unit 30, 40 may be driven by a full driving method or a partial driving method such as local dimming, and impulsive driving. The backlight unit 30, 40 may include an optical sheet 40 and an optical layer 30.

The optical sheet 40 may evenly transmit light from the light source to the display panel 10. The optical sheet 40 may be composed of a plurality of layers. For example, the optical sheet 40 may include a prism sheet or a diffusion sheet. Meanwhile, a coupling portion 40d of the optical sheet 40 may be coupled to the frame 50 and/or the back cover 60.

The frame 50 may be located in a rear of the backlight unit 30, 40, and may support the components of the display device 1. The edge of the frame 50 may be fixed to the guide panel 20. For example, components such as backlight unit 30, 40 and a printed circuit board (PCB) on which a plurality of electronic devices are located may be coupled to the frame 50. For example, the frame 50 may include a metal material. The frame 50 may be referred to as a main frame, a module cover, or a cover bottom.

The back cover 60 may cover the rear of the frame 50. The back cover 60 may be coupled to the frame 50. For example, the back cover 60 may include a metal material.

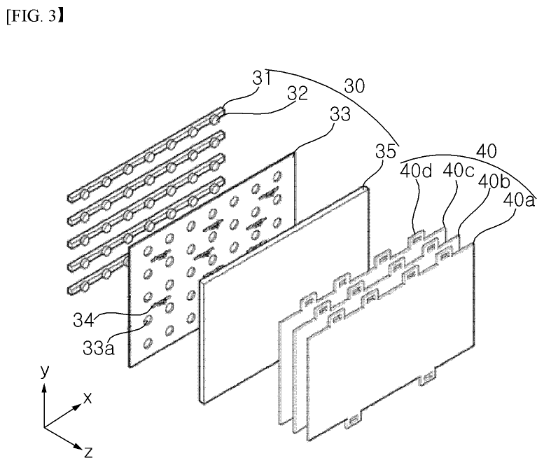

Referring to FIG. 3, the optical layer 30 may include a substrate 31, at least one optical assembly 32, a reflective sheet 33, and a diffusion plate 35. The optical sheet 40 may be located in front of the optical layer 30.

The substrate 31 may extend in the left-right direction, and may be provided in the form of a plurality of straps spaced apart from each other in the vertical direction. At least one optical assembly 32 may be mounted on the substrate 31. An electrode pattern may be formed on the substrate 31 to connect an adapter and the optical assembly 32. For example, the electrode pattern may be a carbon nanotube electrode pattern. The substrate 31 may be composed of at least one of polyethylene terephthalate (PET), glass, polycarbonate (PC), and silicon. The substrate 31 may be a printed circuit board (PCB) on which at least one optical assembly 32 is mounted.

The optical assembly 32 may be a light emitting diode (LED) chip or a light emitting diode package including at least one light emitting diode chip. The optical assembly 32 may be composed of a colored LED or a white LED that emits at least one color among colors such as red, green, and blue. The colored LED may include at least one of red LED, green LED, and blue LED.

The reflective sheet 33 may be located in front of the substrate 31. At least one hole 33a may be formed to penetrate the reflective sheet 33, and the optical assembly 32 may be located in the hole 33a. The reflective sheet 33 may reflect a light provided from the optical assembly 32 or reflected from the diffusion plate 35 forward. For example, the reflective sheet 33 may include a metal having a high reflectivity, such as at least one of aluminum (Al), silver (Ag), gold (Au), and titanium dioxide (TiO2) and/or metal oxide.

In addition, an air gap may be formed between the reflective sheet 33 and the diffusion plate 35. The air gap may serve as a buffer, and the light provided from the optical assembly 32 may be spread widely by the air gap. The supporter 34 may be located between the reflective sheet 33 and the diffusion plate 35, and may form the air gap.

The diffusion plate 35 may be located in front of the reflective sheet 33. The diffusion plate 35 may be located between the reflective sheet 33 and the optical sheet 40.

The optical sheet 40 may include at least one sheet. For example, the optical sheet 40 may include one or more prism sheets and/or one or more diffusion sheets. A plurality of sheets of the optical sheet 40 may be adhered or in close contact with each other.

Specifically, the optical sheet 40 may be composed of a plurality of sheets having different functions. For example, the optical sheet 40 may include a first optical sheet 40a, a second optical sheet 40b, and a third optical sheet 40c. For example, the first optical sheet 40a may be a diffusion sheet, and the second optical sheet 40b and the third optical sheet 40c may be a prism sheet. The diffusion sheet may prevent the light emitting from the diffusion plate 35 from being partially concentrated, thereby making the distribution of light more uniform. The prism sheet may condense the light emitting from the diffusion plate 35 and provide it to the display panel 10. Meanwhile, the number and/or location of the diffusion sheet and the prism sheet may be changed.

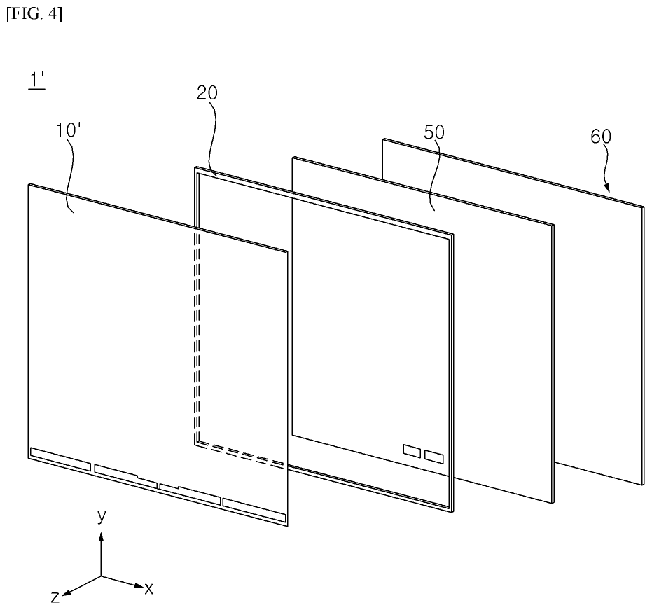

Referring to FIG. 4, a display device 1′ may include a display panel 10′, a guide panel 20, a frame 50, and a back cover 60.

The display panel 10′ may form the front surface of the display device 1′ and may display an image. The display panel 10′ may divide an image into a plurality of pixels and output an image in accordance with color, brightness, and saturation for each pixel. The display panel 10′ may be divided into an active area where image is displayed and a de-active area where image is not displayed. The display panel 10′ may generate light corresponding to the colors of red, green, or blue depending on a control signal. The display panel 10′ may be referred to as an OLED panel.

The guide panel 20′ may surround the circumference of the display panel 10′, and cover the side surface of the display panel 10′. The guide panel 20′ may be coupled to the display panel 10′ or may support the display panel 10′. The guide panel 20′ may be referred to as a side frame or a middle cabinet.

The frame 50 may be located in a rear of the display panel 10′, and the display panel 10′ may be coupled thereto. The edge of the frame 50 may be fixed to the guide panel 20. Electronic components may be mounted in the frame 50. For example, the frame 50 may include a metal material. The frame 50 may be referred to as a main frame, a module cover, or a cover bottom.

The back cover 60 may cover the rear of the frame 50. The back cover 60 may be coupled to the frame 50. For example, the back cover 60 may include a metal material.

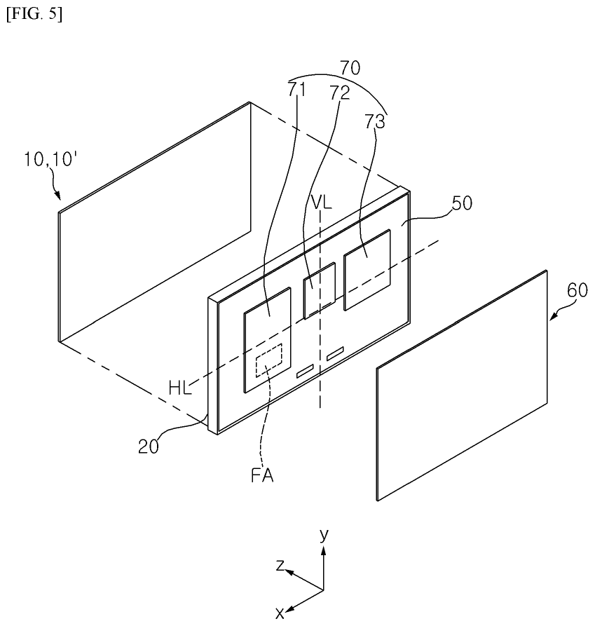

Referring to FIG. 5, boards 70 may be coupled to the frame 50 at the rear of the frame 50. The board 70 may include a plurality of electronic devices. The board 70 may be a printed circuit board (PCB), and may be electrically connected to display device electronic components.

The boards 70 may include a power supply board 71 that provides power to each component of the display device, a timing controller board 72 that provides an image signal to the display panels 10, 10′, and a main board 73 that controls the display device.

For example, the power supply board 71 may be adjacent to the left side of the frame 50. The main board 73 may be adjacent to the right side of the frame 50. The timing controller board 72 may be located between the power supply board 71 and the main board 73.

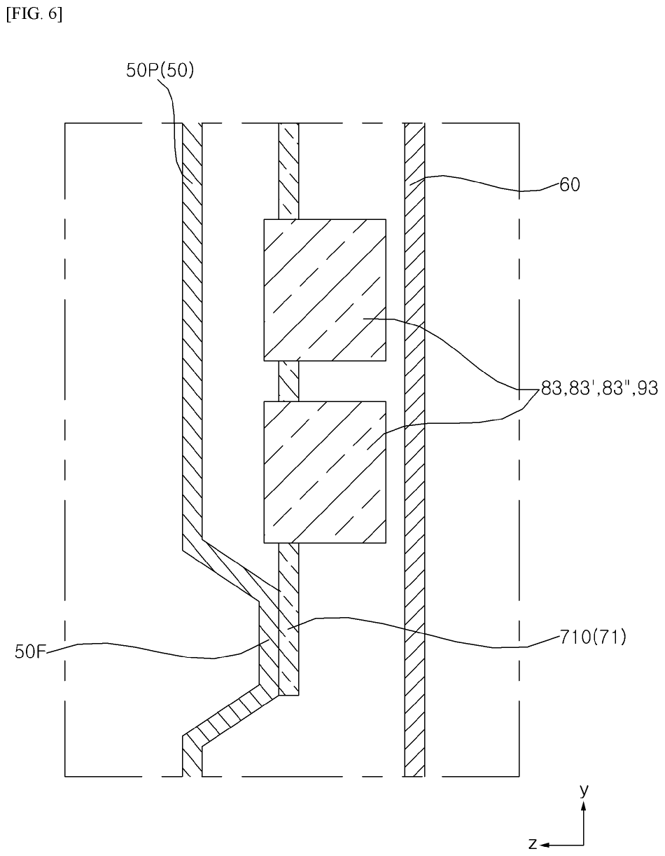

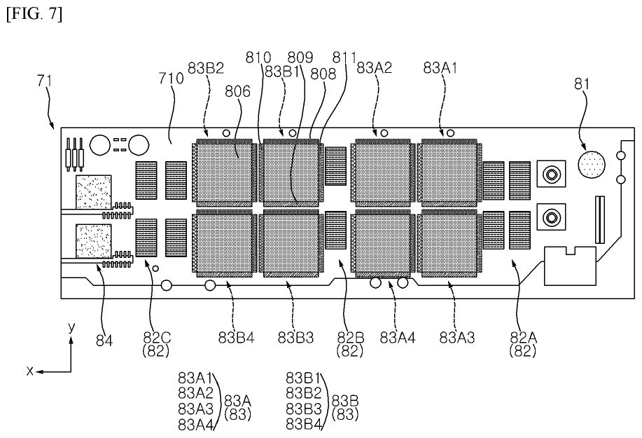

Referring to FIGS. 6 and 7, the power supply board 71 may be fixed to the frame 50 at between the frame 50 and the back cover 60. For example, a press portion 50P may be formed by pressing forward from the rear surface of the frame 50, and may face the power supply board 71. For example, a fixing portion 50F may protrude rearward from the press portion 50P, and a substrate 710 of the power supply board 71 may be fixed thereto.

The line filter 82, 83 may be mounted in the substrate 710. The line filter 82, 83 may be electrically connected to the power supply board 71. The line filter 82, 83 may enhance noise on the power frequency applied to the power supply board 71. The line filter 82, 83 may be referred to as an Electro Magnetic Interference (EMI) filter. A fuse 81 and a high-frequency filter 84 may be spaced apart from each other with the line filter 82, 83 interposed there-between, and may be mounted in the substrate 710. The line filter 82, 83 may include a capacitor 82 and an inductor 83 that are electrically connected to each other.

For example, the capacitor 82 may include a first capacitor 82A, a second capacitor 82B, and a third capacitor 82C. The first capacitor 82A may be adjacent to the fuse 81, and may be mounted on the substrate 710. For example, the number of first capacitors 82A may be four. The third capacitor 82C may be adjacent to the high frequency filter 84, and may be mounted on the substrate 710. For example, the number of third capacitors 82C may be four. The second capacitor 82B may be located between the first capacitor 82A and the third capacitor 82,C and may be mounted on the substrate 710. For example, the number of second capacitors 82B may be two. Meanwhile, the capacitor 82 may be an X-Capacitor.

For example, the inductor 83 may include a first inductor 83A and a second inductor 83B. The first inductor 83A may be located between the first capacitor 82A and the second capacitor 82B, and may be mounted on the substrate 710. For example, the number of first inductors 83A1, 83A2, 83A3, and 83A4 may be four. The second inductor 83B may be located between the second capacitor 82B and the third capacitor 82C, and may be mounted on the substrate 710. For example, the number of second inductors 83B1, 83B2, 83B3, and 83B4 may be four.

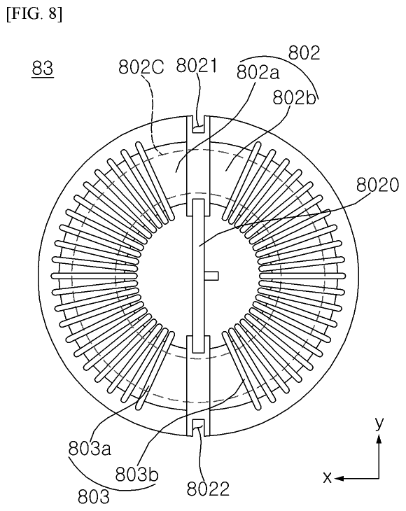

Referring to FIG. 8, the inductor 83 may include a bobbin 802 and a wire 803 wound around the bobbin 802 in a coil shape.

The bobbin 802 may include a plastic material. The bobbin 802 may have an overall ring shape. The bobbin 802 may include a first body 802a and a second body 802b that are adjacent to each other. The first body 802a and the second body 802b may be disposed parallel to the substrate 710 (see FIG. 7) of the power supply board 71. In other words, the first body 802a and the second body 802b may be located on a virtual plane parallel to the substrate 710. The first body 802a may have an arc shape, and may be referred to as a first semicircle. The second body 802b may have an arc shape, and may be referred to as a second semicircle.

The wire 803 may include copper (Cu) material, and allow current to flow. The wire 803 may include a first wire 803a wound around the first body 802a in a coil shape and a second wire 803b wound around the second body 802b in a coil shape. One of the distal end of the first wire 803a and the distal end of the second wire 803b may be connected to a live side, and the other may be connected to a neutral side. Meanwhile, the wire 803 wound around the bobbin 802 may be referred to as a coil 803, a toroidal coil, or an H type coil.

A center core 802C may be inserted into the interior of the first body 802a and the second body 802b. For example, the center core 802C may include ferrite, nano crystal, or amorphous material. For example, the center core 802C may include a plurality of films extending along the circumferential direction of the first body 802a and the second body 802b. The plurality of films may be disposed between the inner circumferential surface and the circumferential surface of the bobbin 802, and may be stacked in the radial direction of the bobbin 802.

Accordingly, the center core 802C may shield the electromagnetic field formed by the flow of current passing through the coil 803.

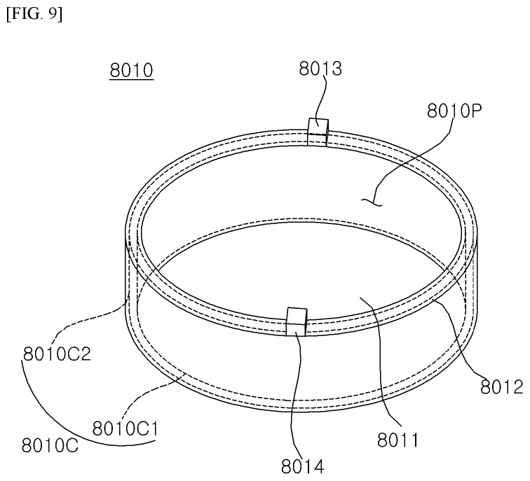

Referring to FIGS. 8 and 9, a bar 8020 may cross the bobbin 802. The bar 8020 may be located at the boundary between the first body 802a and the second body 802b, and may be coupled to the first body 802a and the second body 802b.

A coupling groove 8021, 8022 may be formed in the side surface of the bobbin 802. For example, the coupling groove 8021, 822 may include a first coupling groove 8021 formed in one end of the bar 8020 and a second coupling groove 8022 formed in the other end of the bar 8020.

A cap 8010 may include a plastic material. The cap 8010 may include a circular rear part 8011 and a side part 8012 extending along the circumference of the rear part 8011. For example, the rear part 8011 and the side part 8012 may be formed as one body. The cap 8010 may be open toward the front.

A coupling portion 8013, 8014 may protrude forward from the distal end of the side part 8012. For example, the coupling portion 8013, 8014 may include a first coupling portion 8013 and a second coupling portion 8014 that are spaced apart from each other in the circumferential direction of the side part 8012.

At this time, the first coupling portion 8013 and the second coupling portion 8014 may be coupled to the first coupling groove 8021 and the second coupling groove 8022, respectively.

Accordingly, the cap 8010 may be detachably coupled to the inductor 83 at the rear of the inductor 83. The diameter of the cap 8010 may be larger than the diameter of the bobbin 802. The bobbin 802 may be inserted into an internal space 8010P of the cap 8010. In this case, the rear part 8011 may cover the rear of the bobbin 802 and the coil 803. In addition, the side part 8012 may cover the circumference of the bobbin 802 and the coil 803. Meanwhile, a filler (not shown) made of epoxy bonding or silicone bonding material may surround the inductor 83 in the internal space 8010P of the cap 8010.

Meanwhile, a gap pad (not shown) made of rubber may be coupled to a cap 8010′ at between a cap 8010′ and the back cover 60, and may be in contact with the back cover 60.

A cap core 8010C may be inserted into the interior of the cap 8010. For example, the cap core 8010C may include ferrite, nano crystal, or amorphous material. The cap core 8010C may include a rear core 8010C1 and a side core 8010C2. The rear core 8010C1 may have a shape corresponding to the shape of the rear part 8011, and may be inserted into the interior of the rear part 8011. The side core 8010C2 may have a shape corresponding to the shape of the side part 8012, and may be inserted into the interior of the side core 8012. For example, the rear core 8010C1 and the side core 8010C2 may be formed as one body.

Accordingly, the rear core 8010C1 and the side core 8010C2 may surround the rear and the side surface of the bobbin 802 and the coil 803. That is, the rear core 8010C1 and the side core 8010C2 may shield the electromagnetic field formed by the flow of current passing through the coil 803.

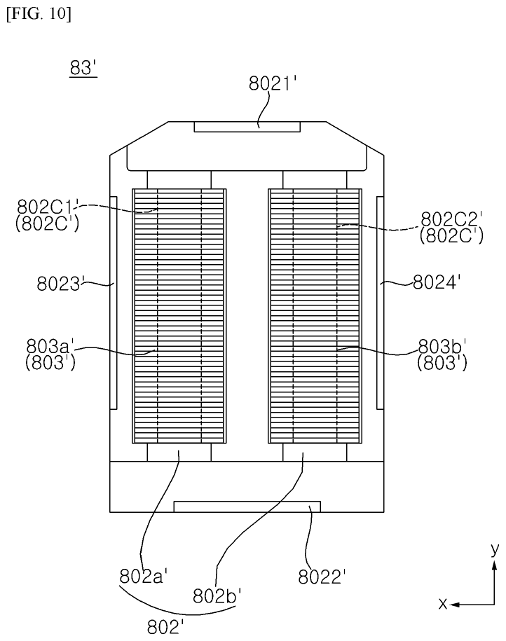

Referring to FIG. 10, an inductor 83′ may include a bobbin 802′ and a wire 803′ wound around the bobbin 802′ in the form of a coil.

The bobbin 802′ may include a plastic material. The bobbin 802′ may include a first body 802a′ and a second body 802b′ extending in the vertical direction. The first body 802a′ and the second body 802b′ may be spaced apart from each other in the left-right direction. The first body 802a′ and the second body 802b′ may be disposed parallel to the substrate 710 (see FIG. 7) of the power supply board 71. In other words, the first body 802a′ and the second body 802b′ may be located on a virtual plane parallel to the substrate 710.

The wire 803′ may include a copper (Cu) material, and allow current to flow. The wire 803′ may include a first wire 803a′ wound in a coil shape around the first body 802a′ and a second wire 803b′ wound in a coil shape around the second body 802b′. One of the distal end of the first wire 803a′ and the distal end of the second wire 803b′ may be connected to the live side, and the other may be connected to the neutral side. Meanwhile, the wire 803′ wound around the bobbin 802′ may be referred to as a coil 803′, an SQ type coil, or an H type coil.

The center core 802C′ may be inserted into the bobbin 802′. For example, the center core 802C′ may include ferrite, nano crystal, or amorphous material. The center core 802C′ may include a first center core 802C1′ and a second center core 802C2′. The first center core 802C1′ may extend long in the vertical direction, and may be inserted into the first body 802a′. The second center core 802C2′ may extend long in the vertical direction, and may be inserted into the second body 802b′. Accordingly, the center core 802C′ may shield the electromagnetic field formed by the flow of current passing through the coil 803′.

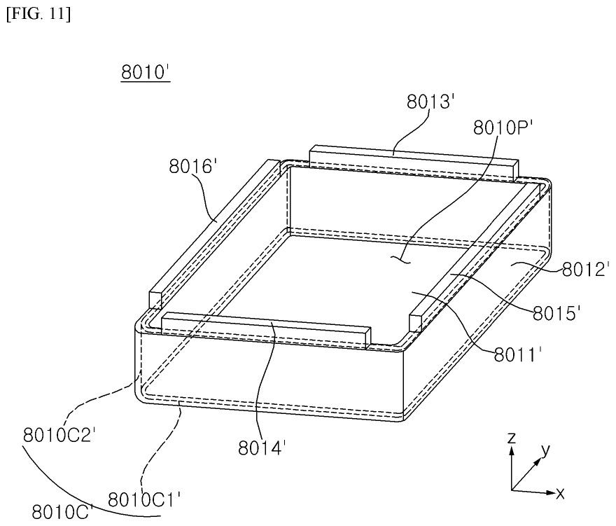

Referring to FIGS. 10 and 11, the cap 8010′ may include a plastic material. The cap 8010′ may include a square rear part 8011′ and a side part 8012′ extending along the circumference of the rear part 8011′. For example, the rear part 8011′ and the side part 8012′ may be formed as one body. The cap 8010′ may be open toward the front.

A coupling portion 8013′, 8014′, 8015′, and 8016′ may protrude forward from the distal end of the side part 8012′. For example, the coupling portion 8013′, 8014′, 8015′, and 8016′ may include a first coupling portion 8013′, a second coupling portion 8014′, a third coupling portion 8015′, and a fourth coupling portion 8016′ that are spaced apart from each other in the circumferential direction of the side part 8012′. The first coupling portion 8013′ may protrude forward from the front end of the upper portion of the side part 8012′. The second coupling portion 8014′ may protrude forward from the front end of the lower portion of the side part 8012′. The third coupling portion 8015′ may protrude forward from the front end of the left portion of the side part 8012′. The fourth coupling portion 8016′ may protrude forward from the front end of the right portion of the side part 8012′.

A coupling groove 8021′, 8022′, 8023′, and 8024′ may be formed on the side surface of the bobbin 802′. For example, the coupling groove 8021′, 8022′, 8023′, and 8024′ may include a first coupling groove 8021′, a second coupling groove 8022′, a third coupling groove 8023′, and a fourth coupling groove 8024′ that are spaced apart from each other in the circumferential direction of the bobbin 802′. The first coupling groove 8021′ may be formed on the upper side of the bobbin 802′. The second coupling groove 8022′ may be formed on the lower side of the bobbin 802′. The third coupling groove 8023′ may be formed on the left side of the bobbin 802′. The fourth coupling groove 8024′ may be formed on the right side of the bobbin 802′.

At this time, the first coupling portion 8013′, the second coupling portion 8014′, the third coupling portion 8015′, and the fourth coupling portion 8016′ may be coupled to the first coupling groove 8021′, the second coupling groove 8022′, the third coupling groove 8023′, and the fourth coupling groove 8024′, respectively.

Accordingly, the cap 8010′ may be detachably coupled to the inductor 83′ in the rear of the inductor 83′. The size of the cap 8010′ may be larger than the size of the bobbin 802′. The bobbin 802′ may be inserted into the internal space 8010P′ of the cap 8010′. In this case, the rear part 8011′ may cover the rear of the bobbin 802′ and the coil 803′. In addition, the side part 8012′ may cover the circumference of the bobbin 802′ and the coil 803′. Meanwhile, a filler (not shown) made of epoxy bonding or silicone bonding material may surround the inductor 83′ in the internal space 8010P′ of the cap 8010′. Meanwhile, a gap pad (not shown) made of rubber may be coupled to the cap 8010′ at between the cap 8010′ and the back cover 60, and may be in contact with the back cover 60.

A cap core 8010C′ may be inserted into the interior of cap 8010′. For example, the cap core 8010C′ may include ferrite, nano crystal, or amorphous material. The cap core 8010C′ may include a rear core 8010C1′ and a side core 8010C2′. The rear core 8010C1′ may have a shape corresponding to the shape of the rear part 8011′, and may be inserted into the interior of the rear part 8011′. The side core 8010C2′ may have a shape corresponding to the shape of the side part 8012′, and may be inserted into the interior of the side part 8012′. For example, the rear core 8010C1′ and the side core 8010C2′ may be formed as one body.

Accordingly, the rear core 8010C1′ and the side core 8010C2′ may surround the rear and the side surface of the bobbin 802′ and the coil 803′. That is, the rear core 8010C1′ and the side core 8010C2′ may shield the electromagnetic field formed by the flow of current passing through the coil 803′.

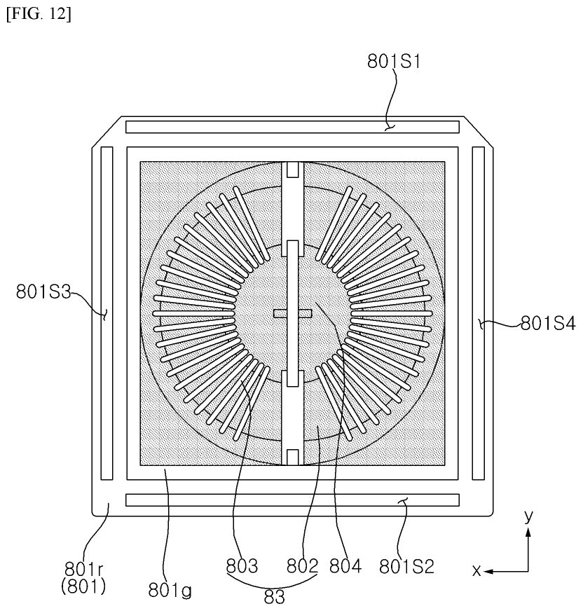

Referring to FIG. 12, the housing 801 may include a plastic material. The housing 801 may have an overall box shape. The housing 801 may be opened in the front-rear direction.

The inductor 83 described above with reference to FIG. 8 or the inductor 83′ described with reference to FIG. 10 may be accommodated in the internal space of the housing 801. Hereinafter, for brief explanation, the description will be made based on the inductor 83 described above with reference to FIG. 8.

The bobbin 802 may be fixed to the inside of the housing 801. A filler 804 may be filled in the internal space of the housing 801, and may surround the inductor 83. For example, the filler 804 may include an epoxy bonding or silicone bonding material. Accordingly, the filler 804 may alleviate the vibration and noise of the coil 803 of the inductor 83.

A groove 801g may be formed by recessing forward from a rear surface 801r of the housing 801. The groove 801g may extend along the circumference of housing 801. The upper portion of the groove 801g may extend along the upper side of the housing 801, and may be adjacent to the upper side of the housing 801. The lower portion of the groove 801g may extend along the lower side of the housing 801, and may be adjacent to the lower side of the housing 801. The left portion of the housing 801 may extend along the left side of the housing 801, and may be adjacent to the left side of the housing 801. The right portion of housing 801 may extend along the right side of housing 801, and may be adjacent to the right side of housing 801.

In addition, the groove 801g may be flat. The groove 801g may be located in a rear of the inductor 83 and the filler 804. The opening of the housing 801 described above may be formed inside the groove 801g.

A plurality of slots 801S1, 801S2, 801S3, and 801S4 may be adjacent to the edge of the housing 801, and may be formed to penetrate the housing 801. A first slot 801S1 may extend along the upper side of the housing 801, and may be located between the upper side of the housing 801 and the upper portion of the groove 801g. A second slot 801S2 may extend along the lower side of the housing 801, and may be located between the lower side of the housing 801 and the lower portion of the groove 801g. A third slot 801S3 may extend along the left side of the housing 801, and may be located between the left side of the housing 801 and the left portion of the groove 801g. A fourth slot 801S4 may extend along the right side of the housing 801, and may be located between the right side of the housing 801 and the right portion of the groove 801g.

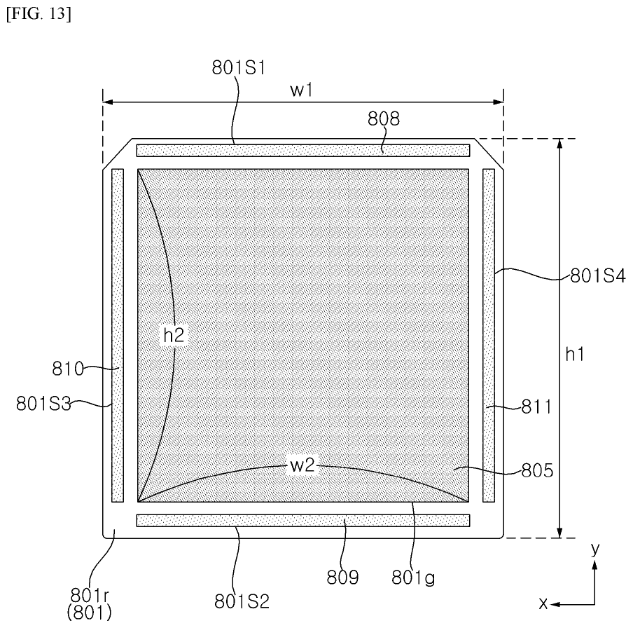

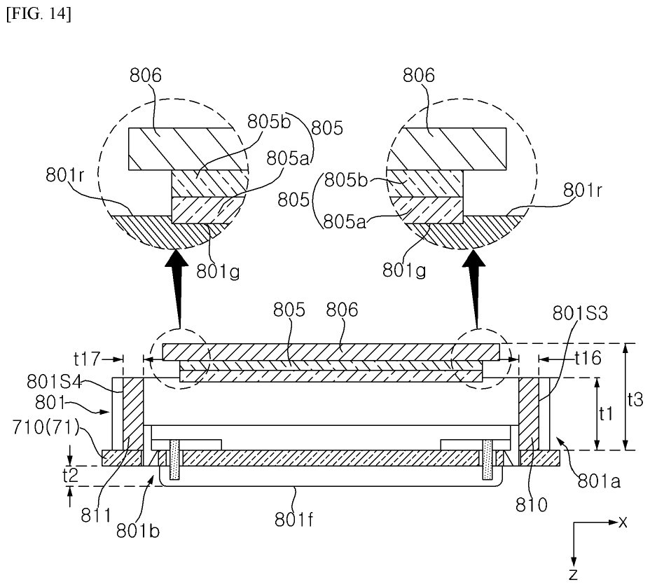

Referring to FIGS. 13 and 14, the rear core 805 may be seated on the groove 801g, and cover the opening of the housing 801 described above. For example, the rear core 805 may be coupled to the groove 801g through an adhesive member such as double-sided tape. The rear core 805 may have a square plate shape. The width w2 of the rear core 805 may be smaller than the width w1 of the housing 801, and the height h2 of the rear core 805 may be smaller than the height h1 of the housing 801.

In this case, compared to the case where the rear core 805 is directly coupled to the filler 804, the rear core 805 may be disposed flat on the housing 801. That is, it is possible to prevent noise deviation due to uneven flatness of the rear core 805 with respect to the housing 801.

In addition, at least a portion of the side surface of the rear core 805 may contact a step formed between the rear surface 801r of the housing 801 and the groove 801g. That is, the convenience and stability of coupling the rear core 805 to the housing 801 may be improved.

For example, the rear core 805 may include ferrite, nano crystal, or amorphous material. For example, the rear core 805 may include a single sheet of ferrite material. For another example, the rear core 805 may include a first sheet 805a made of aluminum material and a second sheet 805b made of ferrite material. In this case, the first sheet 805a and the second sheet 805b may be coupled to each other through an adhesive member such as double-sided tape, and may be collectively referred to as a composite shielding sheet.

The upper core 808 may be inserted and fixed into the first slot 801S1. The lower core 809 may be inserted and fixed into the second slot 801S2. The left core 810 may be inserted and fixed into the third slot 801S3. The right core 811 may be inserted and fixed into the fourth slot 801S4.

For example, the upper core 808, the lower core 809, the left core 810, and the right core 811 may include the same material as the rear core 805. For example, the upper core 808, the lower core 809, the left core 810, and the right core 811 may have the same thickness as the rear core 805.

The aforementioned rear core 805, upper core 808, lower core 809, left core 810, and right core 811 may be spaced apart from each other. In addition, the rear core 805, upper core 808, lower core 809, left core 810, and right core 811 may be disposed to surround the rear and the side surface of the bobbin 802 (see FIG. 12) and the coil 803 (see FIG. 12). That is, the rear core 805, upper core 808, lower core 809, left core 810, and right core 811 may shield the electromagnetic field formed by the flow of current passing through the coil 803.

Meanwhile, the housing 801 may penetrate the substrate 710 of the power supply board 71, and may be coupled to the substrate 710. The first part 801a of the housing 801 may be located in a rear of the substrate 710, and may form the rear surface 801r of the housing 801. The second part 801b of the housing 801 may be located in front of the substrate 710, and may form a front surface 801f of the housing 801. A third part (no reference numeral) of the housing 801 may be located between the first part 801a and the second part 801b, and may be inserted into the substrate 710. The above-described first part 801a, second part 801b, and third part may be formed as one body.

The distance t1 between the rear surface of the substrate 710 and the rear surface 801r of the housing 801 may be the thickness t1 of the first part 801a. The distance t2 between the front surface of the substrate 710 and the front surface 801f of the housing 801 may be the thickness t2 of the second part 801b. The thickness t1 of the first part 801a may be greater than the thickness t2 of the second part 801b. For example, the thickness t1 of the first part 801a may be about 9.2 mm, and the thickness t2 of the second part 801b may be about 2.8 mm.

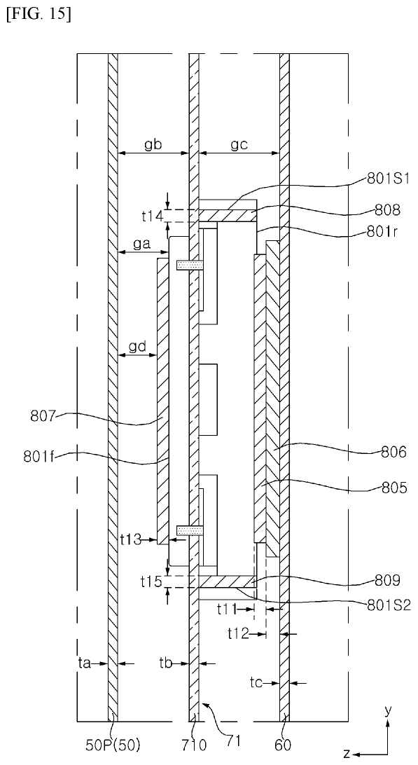

In this case, compared to the case where the housing 801 does not penetrate the substrate 710 and is located on the rear surface of the substrate 710, the gap gc (see FIG. 15) between the substrate 710 and the back cover 60 may be minimized. That is, the disposition of the housing 801 penetrating the substrate 710 may be advantageous in minimizing the thickness of the display device.

Referring to FIGS. 14 and 15, the back cover 60 made of metal may be located in a rear of the housing 801, and adjacent to the housing 801.

The rear core 805 may be located between the housing 801 and the back cover 60, and may cover the rear of the inductor 83 (see FIG. 12) accommodated inside the housing 801.

That is, the rear core 805 may shield the leakage flux of the inductor 83 at between the inductor 83 and the back cover 60. Accordingly, the rear core 805 may prevent the formation of an eddy current in the back cover 60 due to the electromagnetic field of the inductor 83, and reduce vibration and noise of the back cover 60.

For example, the thickness t11 of the rear core 805 may be determined based on the maximum value of the current flowing in the power supply board 71, the thickness ta of the frame 50, and/or the thickness tc of the back cover 60. That is, the thickness t11 of the rear core 805 may be proportional to the maximum value of the current flowing in the power supply board 71, and may be inversely proportional to the thickness ta of the frame 50 and the thickness tc of the back cover 60. For example, the thickness ta of the frame 50 and the thickness tc of the back cover 60 may be about 0.8 mm. For example, the thickness t11 of the rear core 805 may be about 2.0 mm.

The gap pad 806 made of rubber may be located between the rear core 805 and the back cover 60. The gap pad 806 may be coupled to the rear surface of the rear core 805 through an adhesive member such as double-sided tape, and may be in contact with the inner surface of the back cover 60. In other words, the thickness t12 of the gap pad 806 may be substantially equal to the gap between the rear core 805 and the back cover 60. For example, the thickness t12 of the gap pad 806 may be about 1.5 to 2.0 mm. Accordingly, the gap pad 806 may reduce vibration and noise of the back cover 60.

The frame 50 made of metal may be located in front of the housing 801, and may be adjacent to the housing 801. The gap ga between the front surface 801f of the housing 801 and the frame 50 may be smaller than the gap gb between the front surface of the substrate 710 and the frame 50.

The above-described upper core 808, lower core 809, left core 810, and right core 811 may be located in a rear of the substrate 710, and may be disposed to surround the side surface of the inductor 83 (see FIG. 12) accommodated inside the housing 801.

That is, the upper core 808, lower core 809, left core 810, and right core 811 may shield the leakage flux of the inductor 83 directed to the upper, lower, left, and right sides of the housing 801. Accordingly, the upper core 808, lower core 809, left core 810, and right core 811 may prevent the formation of eddy current in the frame 50 and the back cover 60 due to the electromagnetic field of the inductor 83, and may reduce the vibration and noise of the frame 50 and back cover 60. Meanwhile, the upper core 808 and the lower core 809 may be collectively referred to as vertical core 808, 809, and the left core 810 and the right core 811 may be collectively referred to as a horizontal core 810, 811. In addition, the vertical core 808, 809 and the horizontal core 810, 811 may be collectively referred to as a side core 808, 809, 810, 811.

Meanwhile, the front core 807 may be located between the housing 801 and the frame 50, and may cover the front of the inductor 83 (see FIG. 8) accommodated inside the housing 801. The front core 807 may be coupled to the front surface 801f of the housing 801 through an adhesive member such as double-sided tape, and may be spaced apart from the frame 50. The gap gd between the front surface of the front core 807 and the frame 50 may be smaller than the gap ga between the front surface 801f of the housing 801 and the frame 50. For example, the material and thickness t13 of the front core 807 may be the same as the material and thickness t11 of the rear core 805 described above.

That is, the front core 807 may shield the leakage flux of the inductor 83 at between the inductor 83 and the frame 50. Accordingly, the front core 807 may prevent the formation of an eddy current in the frame 50 due to the electromagnetic field of the inductor 83, and reduce vibration and noise of the frame 50.

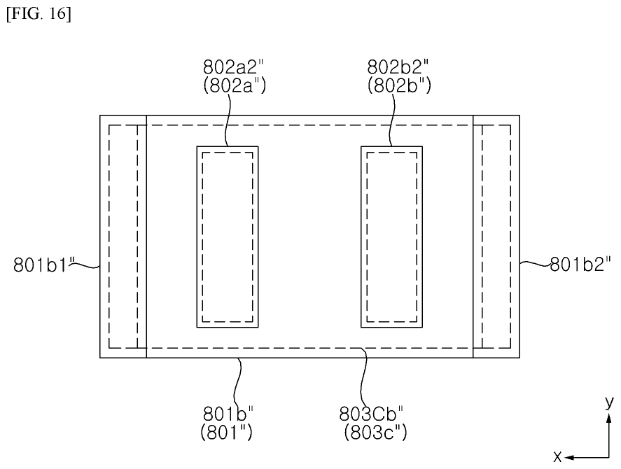

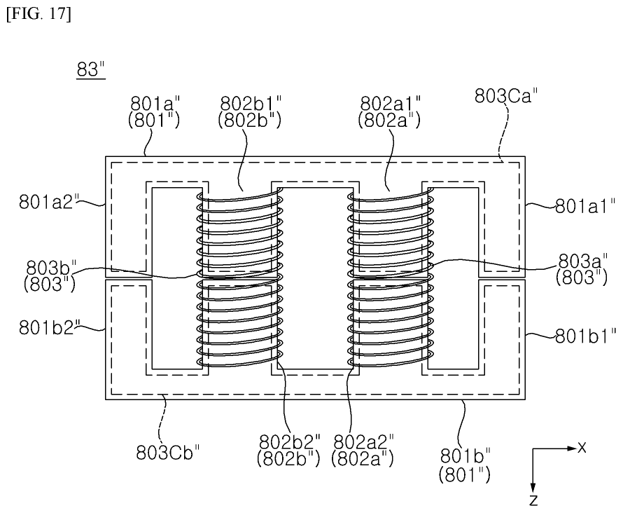

Referring to FIGS. 16 and 17, the inductor 83″ may include a bobbin 801″ and a wire 803″ wound around the bobbin 801″ in the form of a coil.

The bobbin 801″ may include a plastic material. For example, the bobbin 801″ may include a first bobbin 801a″ and a second bobbin 801b″ that are detachably coupled to each other in the front-rear direction. For another example, the bobbin 801″ may be formed as one body. The first bobbin 801a″ and the second bobbin 801b″ may be disposed perpendicularly to the substrate 710 (see FIG. 7) of the power supply board 71. In other words, the first bobbin 801a″ and the second bobbin 801b″ may be located on a virtual plane perpendicular to the substrate 710.

A first flat plate portion (no reference numeral) of the first bobbin 801a″ may extend in the left-right direction, and may form the rear surface of the bobbin 801″. In addition, the first bobbin 801a″ may include a first left body 802a1″ and a first right body 802b1″ that extend forward from the first flat plate portion. The first left body 802a1″ and the first right body 802b1″ may be spaced apart from each other in the left-right direction. In addition, the first bobbin 801a″ may include a first left wall 801a1″ and a first right wall 801a2″ that extend forward from the first flat plate portion. The first left wall 801a1″ may be spaced to the left from the first left body 802a1″, and may cover the left side of the first left body 802a1″. The first right wall 801a2″ may be spaced to the right from the first right body 802b1″, and may cover the right side of the first right body 802b1″.

A second flat plate portion (no reference numeral) of the second bobbin 801b″ may extend in the left-right direction, and may form the front surface of the bobbin 801″. In addition, the second bobbin 801b″ may include a second left body 802a2″ and a second right body 802b2″ that extend rearward from the second flat plate portion. The second left body 802a2″ and the second right body 802b″ may be spaced apart from each other in the left-right direction. In addition, the second bobbin 801b″ may include a second left wall 801b1″ and a second right wall 801b2″ that extend forward from the second flat plate portion. The second left wall 801b1″ may be spaced to the left from the second left body 802a2″, and may cover the left side of the second left body 802a2″. The second right wall 801b2″ may be spaced to the right from the second right body 802b2″, and may cover the right side of the second right body 802b2″.

At this time, the first left body 802a1″ and the second left body 802a2″ may be in contact with each other, and may be collectively referred to as the left body 802a″ or the first body 802a″. The first right body 802b1″ and the second right body 802b2″ may be in contact with each other, and may be collectively referred to as the right body 802b″ or the second body 802b″. The first left wall 801a1″ and the second left wall 801b1″ may be in contact with each other, and may be collectively referred to as the left wall 801a1″, 801b1″ or the first wall 801a1″, 801b1″. The first right wall 801a2″ and the second right wall 801b2″ may be in contact with each other, and may be collectively referred to as the right wall 801a2″, 801b2″ or the second right wall 801a2″, 801b2″. In this case, the bobbin 801″ may be opened in the up-down direction.

The wire 803″ may include copper (Cu) material, and allow current to flow. The wire 803″ may include a first wire 803a″ wound in a coil shape around the left body 802a″ and a second wire 803b″ wound in a coil shape around the right body 802b″. One of the distal end of the first wire 803a″ and the distal end of the second wire 803b″ may be connected to the live side, and the other may be connected to the neutral side. Meanwhile, the wire 803″ wound around the bobbin 801″ may be referred to as a coil 803″ or a V type coil.

A first core 803Ca″ may be inserted into the first bobbin 801a″. For example, the first core 803Ca″ may include ferrite, nano crystal, or amorphous material. The first core 803Ca″ may have a shape corresponding to the shape of the first bobbin 801a″. A first portion (no reference numeral) of the first core 803Ca″ may have a shape corresponding to the shape of the first flat plate portion. A second portion (no reference numeral) of the first core 803Ca″ may have a shape corresponding to the shape of the first left body 802a1″ and the first right body 802b1″. A third portion (no reference numeral) of the first core 803Ca″ may have a shape corresponding to the shape of the first left wall 801a1″ and the first right wall 801a2″. For example, the first portion, the second portion, and the fourth portion may be formed as one body.

A second core 803Cb″ may be inserted into the second bobbin 801b″. For example, the second core 803Cb″ may include ferrite, nano crystal, or amorphous material. The second core 803Cb″ may have a shape corresponding to the shape of the second bobbin 801b″. A first portion (no reference numeral) of the second core 803Cb″ may have a shape corresponding to the shape of the second flat plate portion. A second portion (no reference numeral) of the second core 803Cb″ may have a shape corresponding to the shape of the second left body 802a2″ and the second right body 802b2″. A third portion (no reference numeral) of the second core 803Cb″ may have a shape corresponding to the shape of the second left wall 801b1″ and the second right wall 801b2″. For example, the first portion, the second portion, and the third portion may be formed as one body.

Accordingly, the first core 803Ca″ and the second core 803Cb″ may shield the electromagnetic field formed in the flow of current passing through the coil 803″, and may be collectively referred to as a center core 803Ca″, 803Cb″.

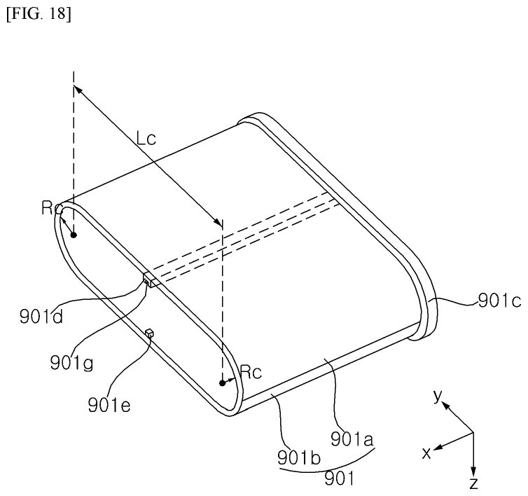

Referring to FIG. 18, the housing 901 may include a plastic material. The housing 901 may extend long in the left-right direction. The housing 901 may be opened in the left and right sides. The cross section of the housing 901 may have a track shape. In this case, the housing 901 may include a pair of straight sections 901S and a pair of curved sections 901R. A pair of straight sections 901S may extend in the vertical direction, and may be spaced apart from each other in the front-rear direction. A pair of curved sections 901R may face each other with respect to the pair of straight sections 901S, and be connected to the pair of straight sections 901S.

For example, the housing 901 may include a first housing 901a and a second housing 901b that are detachably coupled to each other in the front-rear direction through a snap fit structure or the like. For another example, the housing 901 may be formed as one body.

A rib 901c may protrude from the right distal end of the housing 901 to the outside of the housing 901. The rib 901c may extend along the circumference of the housing 901.

A rail 901d may protrude from the inner surface of the housing 901 toward the internal space of the housing 901. The guide rail 901d may extend long in the longitudinal direction of the housing 901, that is, in the left-right direction. A groove 901g may be formed in one side of the rail 901d, and may be long along the rail 901d. For example, in the front-rear direction, the groove 901g may be aligned with the center line of the first housing 901a.

A protrusion 901e may protrude from the inner surface of the housing 901 toward the internal space of the housing 901, and may face the rail 901d. The protrusion 901e may be adjacent to the left distal end of the housing 901.

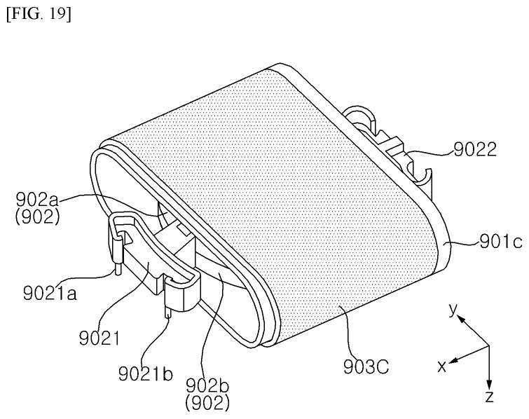

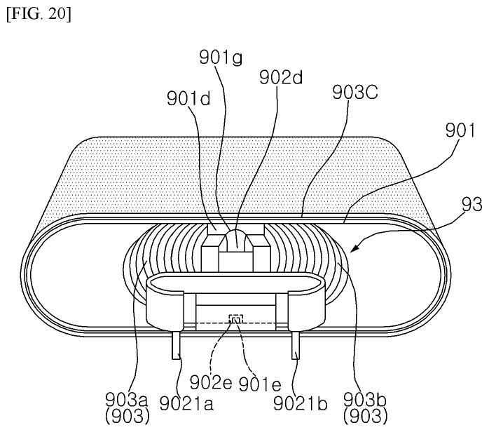

Referring to FIGS. 19 and 20, an inductor 93 may include a bobbin 902 and a wire 903 wound around the bobbin 902 in a coil shape. The inductor 93 may correspond to the inductor 83 described above with reference to FIG. 8, the inductor 83′ described above with reference to FIG. 10, or the inductor 83″ described above with reference to FIG. 17. In other words, any one of the inductors 93, 83, 83′, and 83″ may be accommodated inside the housing 901 described above and below.

The bobbin 902 may include a plastic material. The bobbin 902 may have an overall ring shape. The bobbin 902 may include a first body 902a and a second body 902b that are connected to each other. The first body 902a may have an arc shape, and may be referred to as a first semicircle. The second body 902b may have an arc shape, and may be referred to as a second semicircle.

The wire 903 may include copper (Cu) material, and allow current to flow. The wire 903 may include a first wire 903a wound around the first body 902a in a coil shape and a second wire 903b wound around the second body 902b in a coil shape. One of the distal end of the first wire 903a and the distal end of the second wire 903b may be connected to the live side, and the other may be connected to the neutral side. Meanwhile, the wire 903 wound around the bobbin 902 may be referred to as a coil 903, a toroidal coil, or an H type coil.

The bobbin 902 and wire 903 described above may be accommodated in the internal space of the housing 901. In other words, the housing 901 may surround the bobbin 902 and the wire 903.

The center core (not shown) may be inserted into the bobbin 902. For example, the center core may include ferrite, nano crystal, or amorphous material. For example, the center core may include a plurality of films extending along the circumferential direction of the bobbin 902. The plurality of films may be disposed between the inner circumferential surface and circumferential surface of the bobbin 902, and may be stacked in the radial direction of the bobbin 902.

Accordingly, the center core may shield the electromagnetic field formed by the flow of current passing through the coil 903.

A film 903C may include nano crystal or amorphous material. Here, the magnetic permeability of nanocrystal and amorphous may be about 5 to 6 times higher than that of ferrite. In other words, nanocrystal and amorphous may be advantageous in shielding electromagnetic fields due to their thinner thickness compared to ferrite.

In addition, the film 903C may cover the outer surface of the housing 901, and may be attached or coupled to the outer surface. The above-described rib 901c may guide attachment or coupling of the film 903C to the housing 901. For example, the film 903C may be heat treated during such an attachment process. At this time, the curvature of the curved section 901R of the housing 901 may be set within an allowable curvature of the film 903C. Here, the allowable curvature may be the maximum curvature at which the film 903C can be bent without damage. For example, the radius of curvature Rc of the curved section may be 5 mm or more.

Accordingly, the film 903C may shield the electromagnetic field formed by the flow of current passing through the coil 903.

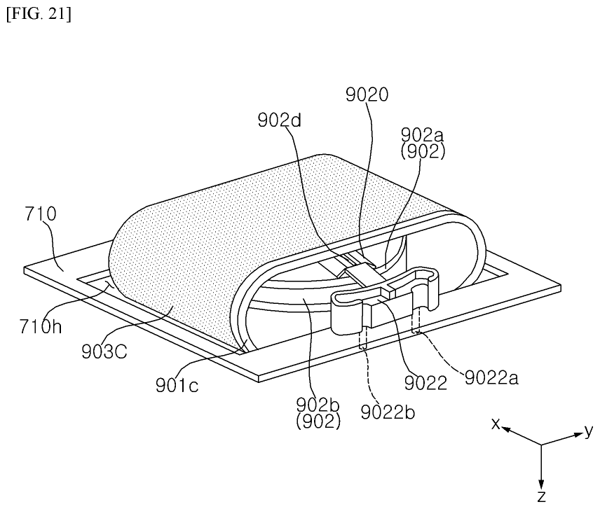

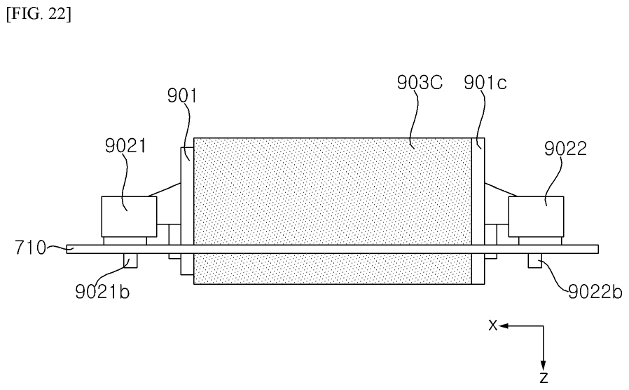

Referring to FIGS. 21 and 22, a bar 9020 may cross the bobbin 902. The bar 9020 may be located at the boundary between the first body 902a and the second body 902b, and may be coupled to the first body 902a and the second body 902b.

An insertion portion 902d may be formed in one side of the bar 9020, and may be movably inserted into the groove 901g of the rail 901d. A hooking portion 902e may be formed in the other side of the bar 9020, and may contact the protrusion 901e. The hooking portion 902e may have elasticity. That is, in response to the slide movement of the bobbin 902, the hooking portion 902e may be hooked to or separated from the protrusion 901e.

Accordingly, the bobbin 902 may be detachably coupled to the housing 901. Meanwhile, unlike the above, the bobbin 902 may be coupled to the housing 901 through a fastening member such as a plastic bolt and rivet.

A first coupling portion 9021 may protrude from one end of the bar 9020 to the outside of the bobbin 902, and may extend along the circumferential direction of the bobbin 902. The first coupling portion 9021 may be referred to as a first arc. A pair of first pins 9021a and 9022b may protrude forward from the first coupling portion 9021, and may be spaced apart from each other in the vertical direction.

A second coupling portion 9022 may protrude from the other end of the bar 9020 to the outside of the bobbin 902, and may extend along the circumferential direction of the bobbin 902. The second coupling portion 9022 may be referred to as a second arc. A pair of second pins 9022a and 9022b may protrude forward from the second coupling portion 9022, and may be spaced apart from each other in the vertical direction.

The above-described first coupling portion 9021 and second coupling portion 9022 may penetrate the substrate 710 of the power supply board 71. The first coupling portion 9021 and the second coupling portion 9022 may be soldered on the rear surface of the substrate 710. Accordingly, the inductor 93 and the housing 901 may be coupled to the substrate 710.

Meanwhile, the housing 901 may penetrate the substrate 710 of the power supply board 71. That is, a portion of the housing 901 may be inserted into the hole 710h of the substrate 710. In this case, compared to the case where the housing 901 does not penetrate the substrate 710 but is located on the rear surface of the substrate 710, a gap between the substrate 710 and the back cover 60 (see FIG. 6) may be minimized. That is, the disposition of the housing 901 penetrating the substrate 710 may be advantageous in minimizing the thickness of the display device.

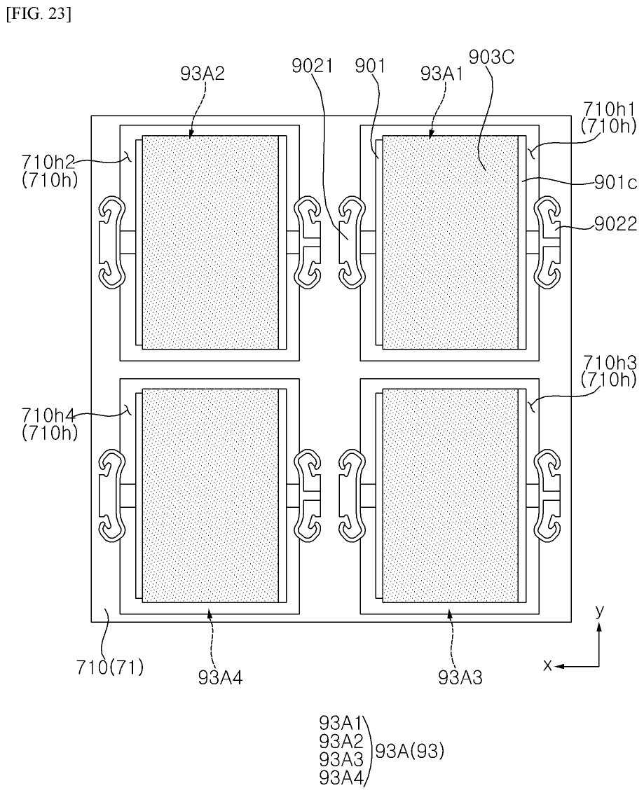

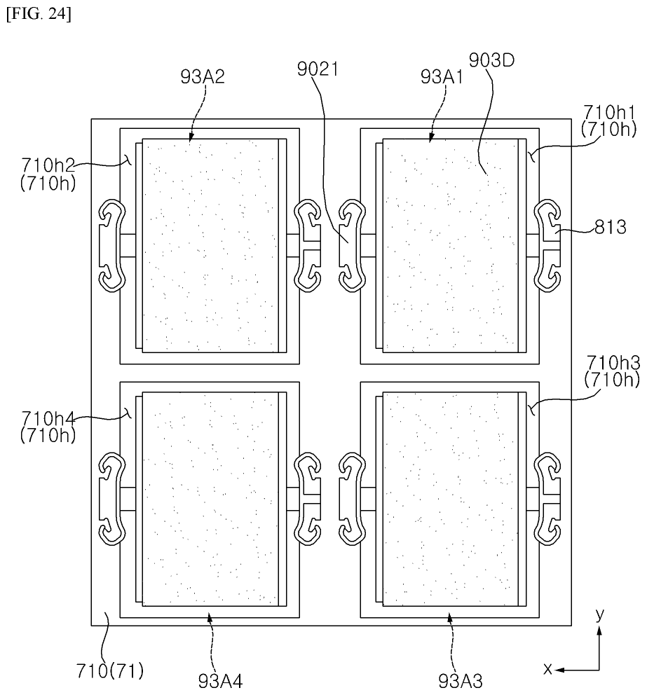

Referring to FIGS. 23 and 24, the inductor 93 may include a plurality of inductors 93A1, 93A2, 93A3, and 93A4 spaced apart from each other. A first inductor 93A1 and a second inductor 93A2 may be spaced apart from each other in the left-right direction. A third inductor 93A3 and a fourth inductor 93A4 may be spaced apart from each other in the left-right direction. The third inductor 93A3 and the fourth inductor 93A4 may be spaced downward from the first inductor 93A1 and the second inductor 93A2.

Accordingly, the plurality of housings 901 accommodating the plurality of inductors 93A1, 93A2, 93A3, and 90A4 may be spaced apart from each other, and may be fixed to the substrate 710.

Meanwhile, a sound absorbing material 903D may be attached or coupled to the surface of the film 903C wound around the housing 901. For example, the sound absorbing material 903D may include a sponge material.

Referring to FIGS. 1 to 24, a display device may include: a display panel; a frame which is located in a rear of the display panel, and to which the display panel is coupled; a back cover covering a rear of the frame; a power supply board which is located between the frame and the back cover, and which is coupled to the frame; and a line filter which is located between the power supply board and the back cover, and which is coupled to the power supply board, wherein the line filter may include: an inductor; and a core which shields at least two side surfaces of the inductor.

The inductor may include: a bobbin which has a first body and a second body that are adjacent to each other; a first wire wound around the first body in a coil shape; and a second wire wound around the second body in a coil shape, wherein the core may be coupled to the bobbin.

The first body and the second body may be disposed parallel to the power supply board.

The first body and the second body may have an overall ring shape, and the display device may further include a center core which is inserted into an interior of the first body and an interior of the second body, which extends along the first body and the second body, and which shields an electromagnetic field.

The first body and the second body may extend in a up-down direction, and which are spaced apart from each other in a left-right direction, and the display device may further include: a first center core which is inserted into an interior of the first body, which extends along the first body, and which shields an electromagnetic field; and a second center core which is inserted into an interior of the second body, which extends along the second body, and which shields an electromagnetic field.

The display device may further include a cap which is opened toward the bobbin, and which is coupled to the bobbin, wherein the bobbin and the wire are accommodated in an inner space of the cap, wherein the cap includes: a rear part which covers a rear of the bobbin and the wire; and a side part which extends along a perimeter of the rear part, and which covers a perimeter of the bobbin and the wire, wherein the core may further include: a rear core which is inserted into an interior of the rear part, and which has a shape corresponding to a shape of the rear part; and a side core which is inserted into an interior of the side part, and which has a shape corresponding to a shape of the side part.

The display device may further include a housing which provides an internal space where the bobbin and the wire are located, and which is coupled to the power supply board, wherein the core may include: a rear core which is coupled to the housing, which is located in a rear of the bobbin and the wire, and which shields an electromagnetic field; and a side core which is coupled to the housing, which faces a perimeter of the bobbin and the wire, and which shields an electromagnetic field.

The back cover and the frame may include a metal material, and the core may further include a front core which is coupled to the housing, which is located in front of the bobbin and the wire, and which shields an electromagnetic field.

The display device further includes a filler that fills the internal space of the housing and which surrounds the bobbin and the wire, and the housing may further include: a groove formed by recessing forward from a rear surface of the housing; and an opening which is formed to penetrate the groove, and which communicates with the internal space of the housing, wherein the groove may be located in a rear of the filler, and the rear core may be seated on the groove, and may covers the opening.

The first body and the second body may be disposed perpendicular to the power supply board.

The first body and the second body may extend in a front-rear direction and may be spaced apart from each other in a left-right direction, the bobbin may further include: a first flat plate portion which extends in a left-right direction, and which is coupled to a rear end of the first body and a rear end of the second body; and a second flat plate portion which extends in a left-right direction, and which is coupled to a front end of the first body and a front end of the second body, wherein the core may further include: a first portion which is inserted into the first flat plate portion, and which has a shape corresponding to a shape of the first flat plate portion; a second portion which is inserted into an interior of the first body and an interior of the second body, and which has a shape corresponding to a shape of the first body and the second body; and a third portion which is inserted into the second flat plate portion, and which has a shape corresponding to a shape of the second flat plate portion.

The bobbin may further include a wall coupled to the first flat plate portion and the second flat plate portion at between the first flat plate portion and the second flat plate portion, the wall having a first wall and a second body which are opposite to each other with respect to the first body and the second body, wherein the core may further include a fourth portion which is inserted into an interior of the first wall and an interior of the second wall, and which has a shape corresponding to a shape of the first wall and the second wall.

The display device may further include a housing which provides an internal space where the bobbin and the wire are located, which is opened in one direction parallel to the power supply board, and which is coupled to the power supply board, wherein the housing may have a track-shaped cross section, and the core may include a film which surrounds an outer surface of the housing, which is attached or coupled to the outer surface of the housing, and which has a nano crystal or amorphous material.

The housing may further include: a pair of straight sections spaced apart from each other; and a pair of curved sections which are opposite to each other with respect to the pair of straight sections, wherein a curvature of the curved section may be within an allowable curvature of the film.

A portion of the inductor may penetrate the power supply board, may be spaced rearwardly from the frame, and may be spaced forwardly from the back cover.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments may be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A display device comprising:
a display panel;
a frame which is located in a rear of the display panel, and to which the display panel is coupled;
a back cover covering a rear of the frame;
a power supply board which is located between the frame and the back cover, and which is coupled to the frame; and
a line filter which is located between the power supply board and the back cover, and which is coupled to the power supply board,
wherein the line filter comprises:
an inductor; and
a core which shields at least two side surfaces of the inductor.

2. The display device of claim 1, wherein the inductor comprises:
a bobbin which has a first body and a second body that are adjacent to each other;
a first wire wound around the first body in a coil shape; and
a second wire wound around the second body in a coil shape,
wherein the core is coupled to the bobbin.

3. The display device of claim 2, wherein the first body and the second body are disposed parallel to the power supply board.

4. The display device of claim 3, wherein the first body and the second body have an overall ring shape,
further comprising a center core which is inserted into an interior of the first body and an interior of the second body, which extends along the first body and the second body, and which shields an electromagnetic field.

5. The display device of claim 3, wherein the first body and the second body extend in a up-down direction, and which are spaced apart from each other in a left-right direction,
further comprising:
a first center core which is inserted into an interior of the first body, which extends along the first body, and which shields an electromagnetic field; and
a second center core which is inserted into an interior of the second body, which extends along the second body, and which shields an electromagnetic field.

6. The display device of claim 3, further comprising a cap which is opened toward the bobbin, and which is coupled to the bobbin,
wherein the bobbin and the wire are accommodated in an inner space of the cap,
wherein the cap comprises:
a rear part which covers a rear of the bobbin and the wire; and
a side part which extends along a perimeter of the rear part, and which covers a perimeter of the bobbin and the wire,
wherein the core further comprises:
a rear core which is inserted into an interior of the rear part, and which has a shape corresponding to a shape of the rear part; and
a side core which is inserted into an interior of the side part, and which has a shape corresponding to a shape of the side part.

7. The display device of claim 3, further comprising a housing which provides an internal space where the bobbin and the wire are located, and which is coupled to the power supply board,
wherein the core comprises:
a rear core which is coupled to the housing, which is located in a rear of the bobbin and the wire, and which shields an electromagnetic field; and
a side core which is coupled to the housing, which faces a perimeter of the bobbin and the wire, and which shields an electromagnetic field.

8. The display device of claim 7, wherein the back cover and the frame comprise a metal material,
wherein the core further comprises a front core which is coupled to the housing, which is located in front of the bobbin and the wire, and which shields an electromagnetic field.

9. The display device of claim 7, further comprising a filler that fills the internal space of the housing and which surrounds the bobbin and the wire,
wherein the housing further comprises:
a groove formed by recessing forward from a rear surface of the housing; and
an opening which is formed to penetrate the groove, and which communicates with the internal space of the housing,
wherein the groove is located in a rear of the filler, and
wherein the rear core is seated on the groove, and covers the opening.

10. The display device of claim 2, wherein the first body and the second body are disposed perpendicular to the power supply board.

11. The display device of claim 10, wherein the first body and the second body extend in a front-rear direction and are spaced apart from each other in a left-right direction,
wherein the bobbin further comprises:
a first flat plate portion which extends in a left-right direction, and which is coupled to a rear end of the first body and a rear end of the second body; and
a second flat plate portion which extends in a left-right direction, and which is coupled to a front end of the first body and a front end of the second body,
wherein the core further comprises:
a first portion which is inserted into the first flat plate portion, and which has a shape corresponding to a shape of the first flat plate portion;
a second portion which is inserted into an interior of the first body and an interior of the second body, and which has a shape corresponding to a shape of the first body and the second body; and
a third portion which is inserted into the second flat plate portion, and which has a shape corresponding to a shape of the second flat plate portion.

12. The display device of claim 11, wherein the bobbin further comprises a wall coupled to the first flat plate portion and the second flat plate portion at between the first flat plate portion and the second flat plate portion, the wall including a first wall and a second body which are opposite to each other with respect to the first body and the second body,
wherein the core further comprises a fourth portion which is inserted into an interior of the first wall and an interior of the second wall, and which has a shape corresponding to a shape of the first wall and the second wall.

13. The display device of claim 2, further comprising a housing which provides an internal space where the bobbin and the wire are located, which is opened in one direction parallel to the power supply board, and which is coupled to the power supply board,
wherein the housing has a track-shaped cross section,
wherein the core comprises a film which surrounds an outer surface of the housing, which is attached or coupled to the outer surface of the housing, and which has a nano crystal or amorphous material.

14. The display device of claim 13, wherein the housing further comprises:
a pair of straight sections spaced apart from each other; and
a pair of curved sections which are opposite to each other with respect to the pair of straight sections,
wherein a curvature of the curved section is within an allowable curvature of the film.

15. The display device of claim 1, wherein a portion of the inductor penetrates the power supply board, is spaced rearwardly from the frame, and is spaced forwardly from the back cover.
